(19) United States
(12) Patent Application Publication
(10) Pub. No.: US 2009/0174051 A1
(43) Pub. Date: Jul. 9, 2009

(54) Semiconductor package and semiconductor device

(76) Inventors: Shuichi Osaka, Nagano (JP); Hitoshi Fujimoto, Hyogo (JP); Tetsuya Hirose, Hyogo (JP); Naoyuki Shinonaga, Nagano (JP)

Correspondence Address: OBLON, SPIVAK, MCCLELLAND MAIER & NEUSTADT, P.C., 1940 DUKE STREET, ALEXANDRIA, VA, 22314, US

(21) Appl. No.: 10/585,092

(22) PCT Filed: Jan. 12, 2005
(86) PCT No.: PCT/JP05/00235

§ 371 Date: Jun. 30, 2006

(51) Int. Cl. H01L 25/04; H01L 23/48

(52) U.S. Cl. 257/686; 257/690; 257/E23.01; 257/E23.141; 257/E25.013

(57) ABSTRACT

A package structure which aims at improvement in function, miniaturization, and systematization of a semiconductor integrated circuit having been made into multichip is offered.

A substrate in which a plurality of terminals for a test and a plurality of terminals for external connection are arranged on the front surface, and a plurality of terminals for internal connection are arranged on the back surface, and a semiconductor chip in which a plurality of surface terminals connected to an internal circuit are formed in the front surface are prepared. An encapsulated semiconductor package is formed by joining the back surface of this semiconductor chip to the back surface of the substrate, connecting the surface terminal of the semiconductor chip to the desired terminal for internal connection of the substrate, and sealing the semiconductor chip on the back surface of the substrate with a molded member. A multichip structure is made by joining the encapsulated semiconductor package to another semiconductor chip mounted on the substrate formed external connection terminals and sealing them.

### INCORPORATION BY REFERENCE

The present application claims priority from PCT application PCT/JP2005/000235 filed on Jan. 12, 2005, the content of which is hereby incorporated by reference into this application.

### TECHNICAL FIELD

The present invention relates to an encapsulated semiconductor package and a semiconductor device incorporating this semiconductor package.

### BACKGROUND ART

Regarding functional improvement, miniaturization, and systematization of a semiconductor device used now, a multichip package which accumulates a plurality of IC chips directly and perpendicularly, and makes wire bonding to an interposer board directly is used centering on a memory kind. (For example, refer to Patent Reference 1, 2).

[Patent Reference 1] Japanese Unexamined Patent Publication No. 2002-231885

[Patent Reference 2] Japanese Unexamined Patent Publication No. 2002-217367

### DISCLOSURE OF THE INVENTION

Since a chip mounting surface is single, generally versatility of a combination of a device is low in the above conventional methods. Further, since electric inspection is conducted after assembly completion of a plurality of chips, there are many generation losses of a defective and a manufacture cost reduction is difficult. Since a degree of freedom of an internal wiring of the wiring is low, a multilayer-structure interposer substrate is needed and problems of rise of substrate cost, and enlargement of bulking of a package etc. occur.

This invention was made in order to solve such a conventional problem. A package structure which aims at improvement in function, miniaturization, and systematization of a semiconductor integrated circuit device is offered by combining a semiconductor package which was tested beforehand and encapsulated, with another highly efficient semiconductor chip.

In order to solve the above problems, an encapsulated semiconductor package is offered in the present invention, first. Namely, a semiconductor package by this invention comprises:

a substrate in which a plurality of terminals for a test and a plurality of terminals for external connection are arranged over a front surface, a plurality of terminals for internal connection are arranged over a back surface, and an internal connection of the terminal for internal connection is made to the desired terminal for a test and/or the terminal for external connection;

at least one semiconductor chip in which a plurality of surface terminals connected to an internal circuit are formed over a front surface, and which is arranged so that a back surface may face the back surface of the substrate;

a wiring which connects the surface terminal of the semiconductor chip to the desired terminal for internal connection of the substrate; and

a molded member which seals the semiconductor chip over the back surface of the substrate.

Further, a semiconductor device in this invention offers a multichip semiconductor device with the above-mentioned encapsulated semiconductor package combining another semiconductor chips which have another functions. Namely, a semiconductor device of this invention comprises:

a main substrate in which a plurality of main terminals for connection are arranged over a main front surface, a plurality of main terminals for external connection are arranged over a back surface, and an internal connection of the main terminal for connection is made to the desired main terminal for external connection;

at least one main semiconductor chip in which a plurality of surface terminals connected to an internal circuit are formed in a main front surface, and which is arranged so that a back surface may face the front surface of the main substrate;

at least one semiconductor package according to this invention arranged so that the molded member may face the front surface of the main semiconductor chip;

wirings which connect the surface terminal of the main semiconductor chip, and the terminal for external connection of the semiconductor package to the desired main terminal for connection of the main substrate; and

a main molded member which seals the main semiconductor chip and the semiconductor package over the front surface of the main substrate.

The other features or modification of the present invention is explained in detail below.

According to the present invention, a semiconductor package which was tested beforehand and encapsulated can be operated by connecting with another semiconductor chips, such as dedicated system LSI which is functioning, combining the chip whose function is different, and systematization can be aimed at easily.

A companion failure that another semiconductor chips combined with this cannot be used in spite of being an excellent article can be eliminated by using a semiconductor package which was tested beforehand and encapsulated. Therefore, the test load can be made into the minimum and the manufacture loss can be prevented.

Since not a bear chip but an encapsulated semiconductor package is used, external leading-out, test, and handling become easy, and the excellent article screening also becomes easy.

### BRIEF DESCRIPTION OF THE DRAWINGS

FIG. 1 is a drawing showing the structure of the semiconductor package in Example 1 of this invention;

FIG. 2 is a drawing showing the structure of the semiconductor package in Example 2 of this invention;

FIG. 3 is a drawing showing the structure of the semiconductor package in Example 3 of this invention;

FIG. 4 is a drawing showing the structure of the semiconductor package in Example 4 of this invention;

FIG. 5 is a drawing showing the structure of the semiconductor package in Example 5 of this invention;

FIG. 6 is a drawing showing the structure of the semiconductor package in Example 6 of this invention;

FIG. 7 is a drawing showing the structure of the semiconductor package in Example 6 of this invention;

FIG. 8 is a drawing showing the structure of the semiconductor package in Example 7 of this invention;

FIG. 9 is a drawing showing the structure of the semiconductor package in Example 8 of this invention;

FIG. 10 is a drawing showing the structure of the semiconductor package in Example 9 of this invention;

FIG. 11 is a drawing showing the structure of the semiconductor package in Example 10 of this invention;

FIG. 12 is a drawing showing the structure of the semiconductor package in Example 11 of this invention;

FIG. 13 is a drawing showing the structure of the semiconductor package in Example 12 of this invention;

FIG. 14 is a drawing showing the structure of the semiconductor package in Example 13 of this invention;

FIG. 15 is a drawing showing the structure of the semiconductor package in Example 14 of this invention;

FIG. 16 is a drawing showing the structure of the semiconductor package in Example 14 of this invention;

FIG. 17 is a drawing showing the structure of the semiconductor package in Example 14 of this invention; and

FIG. 18 is a drawing showing the structure of the semiconductor package in Example 15 of this invention.

### EXPLANATION OF REFERENCE NUMERALS

10 semiconductor package
11 substrate
12 terminal for test
13 terminal for external connection
14 terminal for Internal connection
15 semiconductor chip
16 surface terminal
17 wiring
18 molded member
20 semiconductor device
21 main substrate
22 main terminal for connection
23 main terminal for external connection
24 main semiconductor chip
25 surface terminal
26 fixation material
27a, 27b wiring
28 main molded member
51 spacer
61 adhesive member

### BEST MODE FOR CARRYING OUT THE INVENTION

Examples of this invention are explained in detail with reference to drawings below. The same numerals are given to an identical or a corresponding portion, and explanation is simplified or omitted by a case in each drawing.

### Example 1

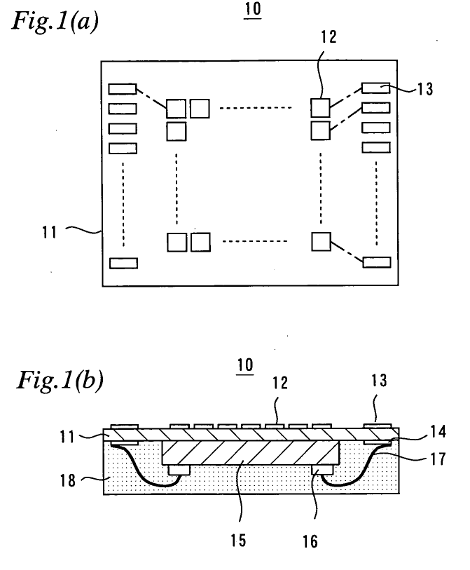

FIG. 1 is a drawing showing the structure of the encapsulated semiconductor package in Example 1 of this invention, the figure (a) shows a plan view and the figure (b) shows a sectional view.

In semiconductor package 10 of FIG. 1, on the surface of substrate 11 called an interposer or an interposer substrate, a plurality of terminals 12 for a test and a plurality of terminals 13 for external connection are arranged, and a plurality of terminals 14 for internal connection are arranged on the back surface. Internal connection of the terminal 14 for internal connection is made to desired terminal 12 for a test. Internal connection of the terminal 14 for internal connection is made also to desired terminal 13 for external connection. Although usually one terminal 12 for a test corresponds to one terminal 13 for external connection in the condition that electric connection is made mutually, there may be terminal 12 for a test without corresponding external connection terminal 13.

Semiconductor chip 15 is arranged so that the back surface side may face the back surface side of this substrate 11, and a plurality of surface terminals 16 connected with that internal circuit are formed on the surface of semiconductor chip 15. Substrate 11 and semiconductor chip 15 may be adhered by an adhesive layer.

And surface terminal 16 of semiconductor chip 15, and desired terminal 14 for internal connection of substrate 11 are connected by wiring 17.

And semiconductor chip 15 and wiring 17 are sealed by molded member 18 at the back surface side of substrate 11.

What is called the “terminal” here, respectively is usually formed with a conductive thin film as a pad for wiring, or a bonding pad. What is called “wiring” is a wiring by which bonding connection is usually made. What is called the “molded member” is usually a resin for sealing. Semiconductor chip 15 is usually joined to substrate 11 via the adhesive layer.

As mentioned above, since desired connection is made with wiring 17 between surface terminal 16 of semiconductor chip 15, and terminal 14 for internal connection of substrate 11, and desired internal connection is made between terminal 14 for internal connection of substrate 11, and terminal 13 for external connection, a predetermined action can be made to semiconductor chip 15 via external connection terminal 13 of substrate 11 from the outside.

Since desired connection is made with wiring 17 between surface terminal 16 of semiconductor chip 15, and terminal 14 for internal connection of substrate 11 and desired internal connection is further made to it between terminal 14 for internal connection of substrate 11, and terminal 12 for a test, a predetermined action of semiconductor chip 15 can be tested via terminal 12 for a test of substrate 11 from the outside.

Next, in the surface of substrate 11, the arrangement area of a plurality of terminals 12 for a test and the arrangement area of a plurality of terminals 13 for external connection are separated as shown in the surface view of substrate 11 of FIG. 1 (a). Concretely, the arrangement area of terminal 13 for external connection is arranged at the periphery of substrate 11, and the arrangement area of terminal 12 for a test is arranged at the inner portion except the periphery of substrate 11.

Next, in the back surface of substrate 11, terminal 14 for internal connection is arranged at the periphery of substrate 11 as understood from the sectional view of substrate 11 of FIG. 1 (b). And semiconductor chip 15 is arranged inside the arrangement area of terminal 14 for internal connection, in other words, in the central part of substrate 11.

Next, molded member 18 is formed on the back surface of substrate 11 with fixed thickness, and this semiconductor package 10 is assuming a rectangle body of fixed thickness as a whole as understood from the sectional view of substrate 11 of FIG. 1 (b).

As explained above, this semiconductor package 10 is electrically connected with an external product by terminals 13 for external connection.

And in substrate 11, terminal 14 for internal connection, terminal 12 for a test, and terminal 13 for external connection are designed so that they may electrically connect and I/O of semiconductor chip 15 and external products may correspond.

Semiconductor chip 15 electrically connects with an external product via wiring 17, terminal 14 for internal connection, terminal 12 for a test, and terminal 13 for external connection, receives a power source and a signal from the outside, and outputs the operation result.

This semiconductor package 10 has an electrical property measured using terminal 12 for a test after an assembly, and it is judged whether it is an excellent article or defective. The product judged to be an excellent article performs a predetermined action, connecting with an external product via terminal 13 for external connection.

Another expressions can explain the above structure as follows.

In semiconductor package 10 of this example, die attachment of the back surface of this semiconductor chip is made on the back surface of interposer substrate 11 of the almost same size as the semiconductor chip (IC chip). And wire bonding between surface terminal 16 (bonding electrode) on the surface of the semiconductor chip, and terminal 14 (electrode for wire bonding) for internal connection wired on the back surface of interposer substrate 11 is made with metal wiring 17. Further, the front surface and the side surface of semiconductor chip 15 are protected by insulating molded member 18 (mold resin).

A plurality of electrically conductive terminals 14 (electrode for wire bonding) for internal connection arranged at the back surface of interposer substrate 11 are wired to the front surface of substrate 11 through the cross section of substrate 11, lead to electrically conductive terminal 12 (electrode for a test) for a test of the front surface of interposer substrate 11, and lead to terminal 13 (external lead-out terminal) for external connection for wire bonding arranged around the front surface of substrate 11.

Terminals 12 (electrode terminal for a test) for a test wired around in the central part of the front surface of substrate 11, and terminals 13 (external lead-out electrode) for external connection for connection with another outside device arranged around the front surface of substrate 11 are separated.

And only an excellent article can be sorted out by testing the function of semiconductor chip 15 (IC chip) beforehand built in using terminal 12 (electrode terminal for a test) for a test of substrate 11.

In semiconductor package 10 of this example, in the front surface of substrate 11, the arrangement area of a plurality of terminals 12 for a test and the arrangement area of a plurality of terminals 13 for external connection can be separated and arranged as shown in FIG. 1 (a). Terminal 13 for external connection may receive damage at the time of the test of a conventional type in which terminal 12 for a test is not independently formed and which uses terminal 13 for external connection for the test. However, even if terminal 12 for a test receives damage, terminal 13 for external connection will be protected without damage in semiconductor package 10 of this example.

When using substrate 11 like this example, the arrangement area of terminal 12 for a test is fully securable. Therefore, the arrangement of a plurality of terminals 12 for a test can be chosen freely. Since the size of each terminal 12 for a test can also be made larger than terminal 13 for external connection, even if the big electric power at the time of the test is applied, there is a merit of being hard to receive damage in the terminal for a test.

Unlike the size of a terminal for external connection, and shape, the size of a terminal for a test and shape can be set as a required size and shape.

As explained above, in this example, a semiconductor package which was explained in the example, and which was encapsulated beforehand using a semiconductor chip which should be made into a multichip combining another highly efficient semiconductor chips is prepared instead of remaining it a bear chip. This encapsulated semiconductor package can be formed small in a size comparable as the chip. Present application inventors are calling this by a nickname of a “chip capsule” or a “chip size capsule”.

When making it a multichip using a bear chip, handling is difficult, but when it is encapsulated like this example, the external leading-out, test, and handling become easy, an excellent article screening also becomes easy and defects of a bear chip can be solved.

And by using a semiconductor package which was tested beforehand and encapsulated, systematization can be easily aimed at as a multi-chip module with which the chip whose function is different operates by connecting with another chips, such as dedicated system LSI which has already functioned, as is explained later.

### Example 2

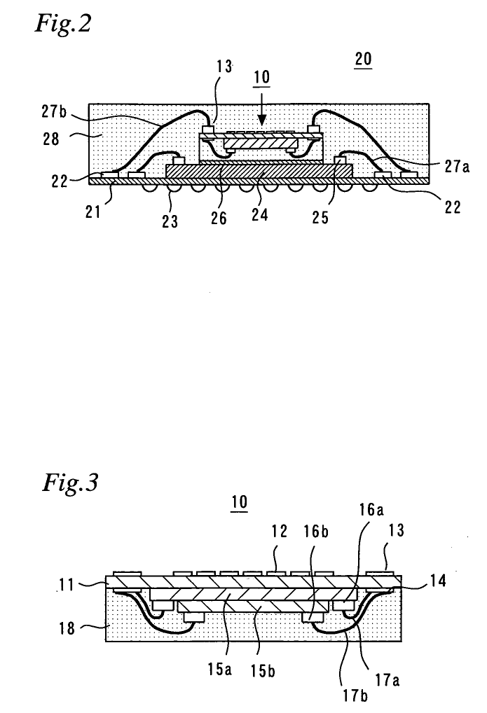

FIG. 2 is a sectional view showing the structure of semiconductor device 20 in Example 2 of this invention. In this semiconductor device 20, semiconductor package 10 which was explained in Example 1 and which was encapsulated is stacked in layers on a semiconductor chip, such as another integrated circuit device, and is made a package product of multichip.

In semiconductor device 20 shown in FIG. 2, a plurality of main terminals 22 for connection are arranged on the main front surface (upper part side of a sectional view) of main substrate 21 called an “interposer” or an “interposer substrate”, and a plurality of main terminals 23 for external connection are arranged on the back surface. And internal connection of the main terminal 22 for connection is made to desired main terminal 23 for external connection.

A main semiconductor chip 24 is arranged on the front surface of main substrate 21, facing the back surface (lower part side of a sectional view) to it, and a plurality of surface terminals 25 connected to a circuit formed in the inside are formed on the main front surface (upper part side of a sectional view) of the main semiconductor chip 24.

Semiconductor package 10 explained in the example is arranged so that the molded member 18 may face the main front surface of the main semiconductor chip 24, and is fixed to the main front surface of the main semiconductor chip 24 with fixation material 26.

Wiring 27a connects surface terminal 25 of the main semiconductor chip 24, and desired main terminal 22 for connection of main substrate 21, and wiring 27b connects terminal 13 for external connection of semiconductor package 10, and desired main terminal 22 for connection of main substrate 21.

Main molded member 28 is sealing the main semiconductor chip 24 and semiconductor package 10 on the main front surface of main substrate 21.

Main terminal 22 for connection of main substrate 21 and surface terminal 25 of the main semiconductor chip 24 are usually formed with the conductive thin film as a pad for wiring, or a bonding pad here. Main terminal 23 for external connection of main substrate 21 is a solder ball for electric connection when usually being mounted on another mounting substrates. What was called wiring 27a and 27b is a wiring by which bonding connection is usually made. It is usually resin for sealing which was called the main molded member 28, and it is usually an adhesive layer by resin which was called fixation material 26.

While the word of “main” is added here like main substrate 21, main terminal 22 for connection, main terminal 23 for external connection, main semiconductor chip 24, and main molded member 28, this is a thing on expedient of only the explanation for aiming at distinction with the words used in Example 1. Although the thing of Example 1 is called a “semiconductor package” and the thing of Example 2 is called a “semiconductor product”, this is a thing on expedient of only explanation to also distinguish both.

As explained above, semiconductor package 10 of this invention that was explained in Example 1 is stacked in layers on the main semiconductor chip 24 (lower-berth chip), as shown in FIG. 2, after that, on the identical main substrate 21 as the main semiconductor chip 24, wire bonding of it is made and resin seal is made. Here, main terminal 22 for connection for main semiconductor chip 24 (lower-berth chip), main terminal 22 for connection for semiconductor package 10, and main terminal 23 for external connection of main substrate 21 are electrically connected into the desired condition, and they are designed to function as an end product. With this semiconductor device 20, the function equivalent to the condition that a plurality of semiconductor chips are stacked in layers can be obtained.

Since an excellent article is beforehand sorted out about semiconductor package 10, generation of companion failure of main semiconductor chip 24 (lower-berth chip) by the defect of semiconductor chip 15 (upper berth chip) stored in semiconductor package 10 can be suppressed.

As mentioned above, semiconductor device 20 of this example bonds together directly to the front surface of another main semiconductor chips 24 (IC chip) the back surface (molded member 18 side opposite to the substrate 11 side) of semiconductor package 10 explained in Example 1 via fixation material 26 etc <or, with an attached spacer>. Terminal 13 (external electrode) for external connection of the front surface side of interposer substrate 11 of semiconductor package 10 is mutually connected to main substrate 21 or above-mentioned another main semiconductor chip 24 (IC chip) by wire bonding, and a compound function is given.

As mentioned above, according to the present invention, a terminal for external connection and a terminal for a test are formed on a front surface, a tested encapsulated semiconductor package of this invention stored and protected in the almost same size as a chip is stacked in layers on another semiconductor chip which has another function, and the semiconductor device which wired mutually with wire bond is manufactured. Hereby, after manufacturing each semiconductor chip, dividing the work, an offer of System-in-Package which can do the system which has a compound function easily is attained.

That is, by unifying and connecting with another chips, such as dedicated system LSI which has already functioned, using the semiconductor package of the present invention tested beforehand, the chip whose function is different can be easily compounded and operated, and systematization can be aimed at easily.

For example, by mounting a semiconductor package of the present invention including a memory chip on a dedicated system LSI chip of the lower berth, a multilayer pile combination of the chip of a plurality of different functions can be made possible, and the versatility of MCP can be raised.

By using the semiconductor package of this invention tested beforehand, a manufacture loss is prevented, a test load is made into the minimum, equipment investment can be suppressed and presentation of a system by a package can be made easy.

Structure of an interposer substrate can be simplified and cost reduction can be aimed at.

Although handling is difficult and a test is not possible as it is in what does an external leading-out with the structure using a conventional bear chip, by using the semiconductor package of the present invention, an external leading-out, a test, and handling become easy, and an excellent article screening also becomes easy.

Since a memory whose excellent article screening was made is combinable with a dedicated system LSI chip etc. for example, without making a dedicated system LSI chip of an excellent article a companion failure combining a defective memory, the effect of productivity improvement is large.

### Example 3

FIG. 3 is a sectional view showing the structure of the semiconductor package by another examples of this invention.

In this example, two semiconductor chips 15a and 15b are arranged on the back surface of substrate 11, and surface terminals 16a and 16b which are arranged on the front surface of semiconductor chips 15a and 15b are connected to terminal 14 for internal connection of the back surface of substrate 11, respectively.

Seeing from the substrate 11 side, surface terminal 16a is arranged at the periphery of the front surface of semiconductor chip 15a of the lower berth, and semiconductor chip 15b of the upper berth is arranged on the non-terminal area of the inside. The semiconductor chips to be stacked in layers are not restricted to two pieces, but those of two or more required number can be stacked in layers. Substrate 11 and semiconductor chips 15a and 15b may be adhered by an adhesive layer. An integration degree can be raised by such stacked layer.

In FIG. 3, surface terminals 16a and 16b of semiconductor chips 15a and 15b seem to be connected to the same terminal 14 for internal connection. However, this is because of a sectional view, and actually, a plurality of terminals 14 for internal connection are arranged at one row in the drawing depth direction, and, generally are connected to different terminal 14 for internal connection.

### Example 4

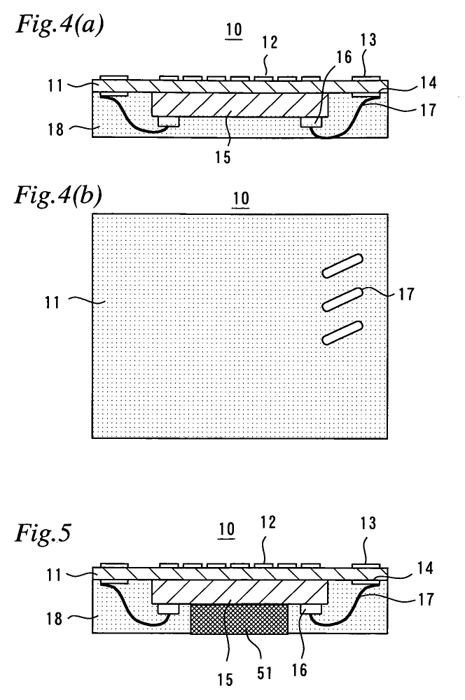

FIG. 4 is a drawing showing the structure of the semiconductor package by another example of this invention, (a) is a sectional view and (b) is a bottom view.

In the semiconductor package shown in FIG. 4, a part of wiring is in the condition that it exposes on the surface of a molded member, and can be seen from the outside. In semiconductor package 10 which was explained by FIG. 1-FIG. 3, internal wiring 17 is buried in molded member 18 so that it may not be visible. When doing in this way, it becomes the tendency for the thickness of molded member 18 to become thick. On the other hand, like the FIG. 4 of this example when wiring 17 may expose to the back surface of semiconductor package 10, the thickness of molded member 18 can be formed thinly.

Although molded member 18 is usually opaque, forming of a transparent member in this case is also considered. Since wiring 17 exposed from molded member 18 is not conspicuous when it is made such, it is desirable on external appearance.

### Example 5

FIG. 5 is a sectional view showing the structure of the semiconductor package by another example of this invention.

In the semiconductor package shown in FIG. 5, spacer 51 of metal, a piece of silicon, or non-conductive is formed on the front surface of semiconductor chip 15, and the front surface is exposed from molded member 18. Spacer 51 may be adhered on semiconductor chip 15 by an adhesive layer. Since heat will be radiated via heat-conductive spacer 51 when doing in this way, heat radiation property improves. When making it adhere to another semiconductor chip using spacer 51 as will be explained later, adhesive property will improve.

### Example 6

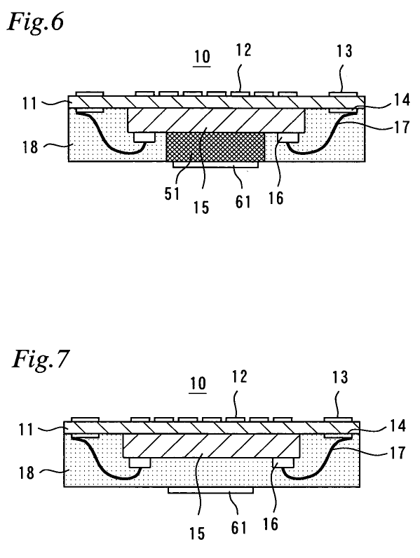

FIG. 6 and FIG. 7 are the sectional views showing the structure of the semiconductor package by another example of this invention, respectively.

In the semiconductor package shown in FIG. 6, adhesive member 61 which includes thermosoftening or thermosetting resin etc. is applied or stuck to the front surface of spacer 51 of semiconductor package 10 shown in FIG. 5. When doing in this way, and joining to another semiconductor chip, the bonding property will improve as will be explained later.

In the semiconductor package shown in FIG. 7, at the back surface side of semiconductor package 10 shown in FIG. 1, adhesive member 61 which includes thermosoftening or thermosetting resin etc. is applied or stuck to the front surface of molded member 18. When doing in this way, and joining to another semiconductor chip, the bonding property will improve as will be explained later.

### Example 7

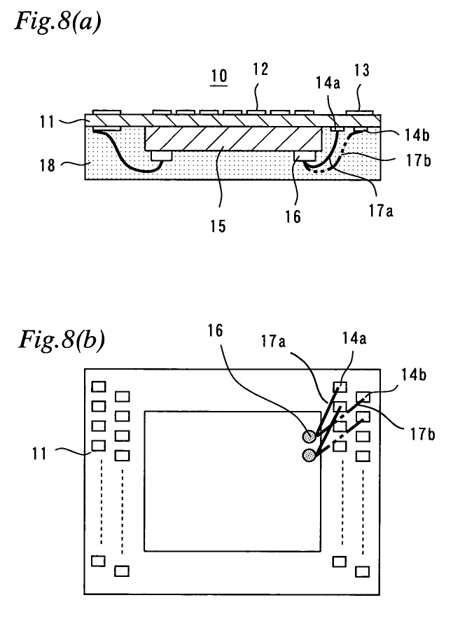

FIG. 8 is a drawing showing the structure of the semiconductor package by another example of this invention, and (a) is the sectional view and (b) is the perspective view seen from the bottom face. In this semiconductor package 10, the terminals for internal connection are formed, dividing into 2 or more sets, and used properly.

FIG. 8 (a) is a sectional view of semiconductor package 10 of this example, and FIG. 8 (b) is a drawing showing arrangement of internal connection terminals 14 of the back surface of substrate 11 and is a perspective view when looking up at FIG. 8 (a) from the bottom.

In semiconductor package 10 shown in this FIG. 8, 2 sets of a plurality of terminals for internal connection of substrate 11 are formed. That is, they are the first group of the row of terminals 14a for internal connection, and the second group of the row of terminals 14b for internal connection.

And desired connection is performed with wiring 17a between surface terminal 16 of semiconductor chip 15, and terminal 14a for internal connection of the first group. Desired connection is performed with wiring 17b between surface terminal 16, and terminal 14b for internal connection of the second group.

Further, the first desired internal connection is performed between terminal 14a for internal connection of the first group, and terminal 13 for external connection. The second desired internal connection is performed between terminal 14b for internal connection of the second group, and terminal 13 for external connection. In other words, such a substrate 11 is prepared.

When doing in this way, a different configuration of connection with an external board or an element is realizable via external connection terminals 13.

Apart from this, a different configuration of connection can be taken with the outside via external connection terminals 13 by mounting semiconductor chip 15 which has a different internal circuit or a different function on the same substrate 11 and using wirings 17a and 17b properly using the same substrate 11.

When explaining this differently further, in the semiconductor package shown in FIG. 8, a plurality of internal connection terminals 14 (bonding pad) for wiring from semiconductor chip 15 in semiconductor package 10 are formed. Although the same chip is used, when the joining pad arrangement which takes conduction with external products differs, even if it is a different configuration of connection, it can be produced by the same substrate by using pads 14a and 14b properly with wires 17a and 17b. That is, communalization of a substrate can be aimed at.

As internal connection terminals 14 (electrode for wire bonding) of the back surface of interposer substrate 11 on which semiconductor chip 15 (IC chip) is mounted, a plurality of internal connection terminals 14 (lead terminal) are arranged so that they can correspond to alteration of an IC chip function. Internal connection terminal 14 (electrode) corresponding to each function can be chosen with wiring 17 of wire bonding.

### Example 8

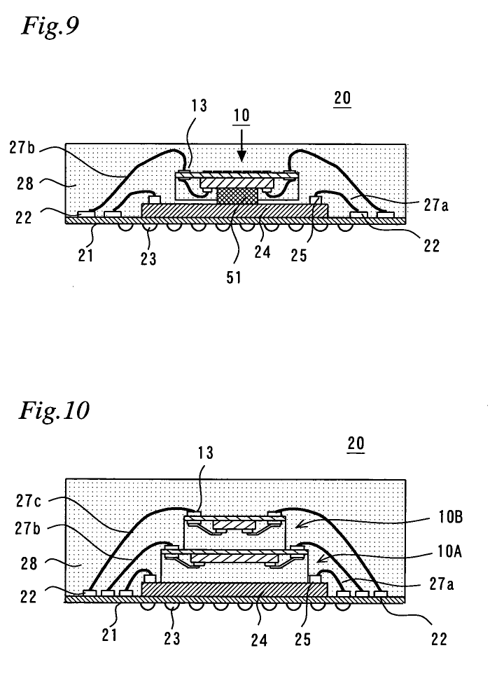

FIG. 9 is a sectional view showing the structure of the semiconductor device by another example of this invention. In this Example 8, like Example 2, a semiconductor package of this invention is stacked in layers on another semiconductor chip (integrated circuit device etc.) to become a package product.

Although semiconductor package 10 as shown in FIG. 1 is mounted on the main semiconductor chip 24 in the FIG. 2 of Example 2, semiconductor package 10 as shown in FIG. 5 is mounted on the main semiconductor chip 24 in the FIG. 9 of this example. That is, the outside surface of spacer 51 of semiconductor package 10 is made to contact the front surface of the main semiconductor chip 24. This may be joined via an adhesive layer.

Spacer 51 of semiconductor package 10 is somewhat high from the front surface of molded member 18, and, in the case of this FIG. 9, has improved bonding property with the front surface of the main semiconductor chip 24.

While making mutual joining easy by forming spacer 51 in semiconductor package 10, and joining to the main semiconductor chip 24 via the spacer in this way, heat radiation property improves.

Each above-mentioned example explained like it might exist only in the two directions about the arrangement of external connection terminal 13 of substrate 11 in semiconductor package 10, the direction of wiring (wire bonding) accompanying it, the arrangement of main terminal 22 for connection of main substrate 21, etc., but these may be two directions and may exist in four directions depending on a thing. The height and shape of semiconductor package 10, semiconductor device 20, and its component can also be set up arbitrarily.

### Example 9

FIG. 10 is a sectional view showing the structure of the semiconductor device by another example of this invention. This example regards a semiconductor device which formed, stacking in layers a plurality of encapsulated semiconductor packages of this invention.

In the semiconductor device shown in FIG. 10, the first semiconductor package 10A of the lower berth is mounted on the main semiconductor chip 24, and the second semiconductor package 10B of the upper berth is further mounted on it.

What made size small so that the terminal for external connection of semiconductor package 10A of the lower berth might be avoided as semiconductor package 10B of an upper berth is stacked in layers. Although it is two stages of stacked layers in FIG. 10, two or more stages, that is, a plurality of stages may be stacked in layers.

Thus, when avoiding external connection terminals of the semiconductor package of the lower berth and making the semiconductor package of an upper berth stack in layers, it will be easy to perform wire bonding to external connection terminals. Further, it is easy to do a test.

As semiconductor package 10 in this case, when terminal 12 for a test and terminal 13 for external connection of substrate 11 are arranged at the periphery of substrate 11, and the central part of substrate 11 is a non-terminal area where a terminal is not arranged, it is convenient to stack in layers.

### Example 10

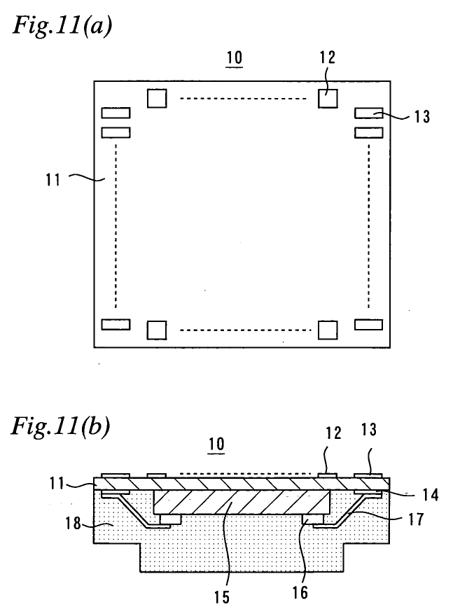

FIG. 11 is a drawing showing the structure of the semiconductor package by another example of this invention, (a) is a plan view and (b) is a sectional view.

In semiconductor package 10 shown in FIG. 11, in substrate 11, the arrangement area of terminal 13 for external connection is arranged at the periphery of facing two sides of substrate 11, and the arrangement area of terminal 12 for a test is arranged at the periphery of another facing two sides of substrate 11. And a non-terminal area where a terminal is not arranged is formed in the central part of substrate 11.

While molded member 18 is formed on the back surface of substrate 11 with fixed thickness, the molded member 18 is formed with relatively small thickness in the portion corresponding to the arrangement area of terminal 13 for external connection of substrate 11. Concretely, the low level difference is formed in the corner part.

When furthermore explaining, in semiconductor package 10 shown in FIG. 11, terminal 12 (pad for a test) for a test will also be arranged as many as possible to the peripheral part of substrate 11 as well as terminal 13 for external connection of interposer substrate 11.

Surface terminal 16 of semiconductor chip 15 and interposer substrate 11 are joined with wiring 17 by a tab, and thinly formed as much as possible in a height direction.

A level difference is formed in molded member 18 (mold resin), as shaved off in the portion corresponding to terminals 13 for external connection of the periphery.

When making it such a structure, it will become possible to stack in layers many semiconductor packages 10 of the same size as will be explained later.

### Example 11

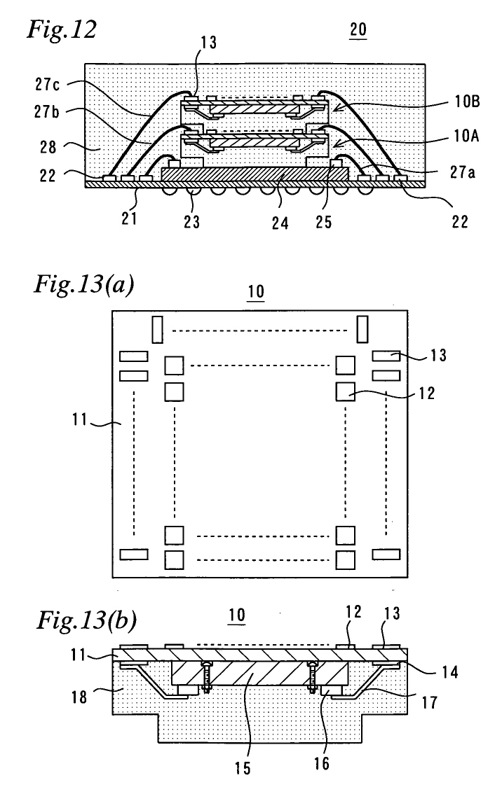

FIG. 12 is a sectional view showing the structure of the semiconductor device by another example of this invention. A semiconductor device of this example regards the semiconductor device which is formed, stacking in layers a plurality of semiconductor packages of Example 10 (FIG. 11).

In the semiconductor device shown in FIG. 12, the first semiconductor package 10A of the lower berth is mounted on the main semiconductor chip 24, and the second semiconductor package 10B of the upper berth is further mounted on it.

Since the level difference is formed in the location corresponding to the terminal for external connection of semiconductor package 10A of the lower berth in semiconductor package 10B of an upper berth, it is easy to make wire bonding to the terminal for external connection, and the height of the whole stacked layer can be suppressed to be low.

When making it such a structure, it will become possible to stack in layers many semiconductor packages of the same size of structure which were explained in Example 10 (FIG. 11).

### Example 12

FIG. 13 is a drawing showing the structure of the semiconductor package by another example of this invention, (a) is a plan view and (b) is a sectional view.

In semiconductor package 10 shown in FIG. 13, in substrate 11, the arrangement area of terminal 13 for external connection is arranged at the most periphery part of substrate 11, the arrangement area of terminal 12 for a test is arranged at the inner portion which adjoins the said periphery of substrate 11, and the non-terminal area where a terminal is not arranged is formed in the central part of substrate 11.

That is, in the semiconductor package shown in FIG. 13, terminals 12 for a test are arranged around interposer substrate 11. And terminals 13 (pad for external connection) for external connection are arranged at the periphery of the terminals 12 for a test.

Surface terminals 16 (pad) are formed on the front surface (main surface) of semiconductor chip 15 like a chip for QFP (Quad Flat Package). Terminals 14 (pad) for internal connection which make TAB connection with surface terminals 16 (pad) of semiconductor chip 15 are formed on the back surface of interposer substrate 11. Further, the same level difference mold as Example 10 (FIG. 11) is performed.

According to this example, it can correspond to CSC (Chip Size Capsule) which has a chip for QFP. The degree of freedom of test pad arrangement increases.

### Example 13

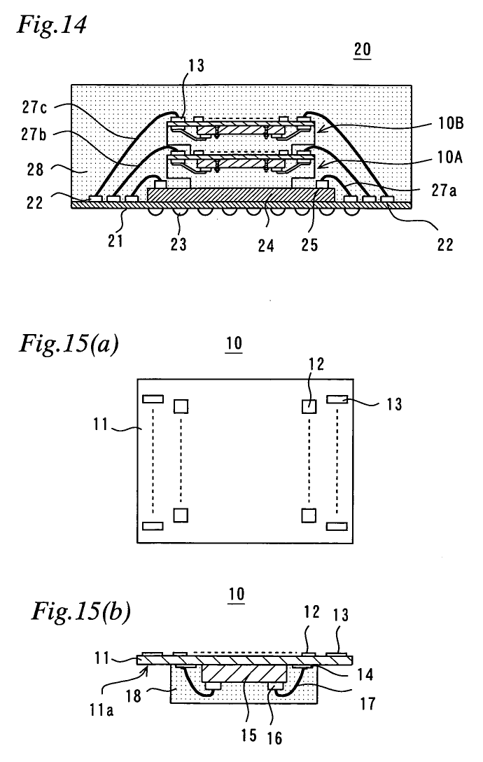

FIG. 14 is a sectional view showing the structure of the semiconductor device by another example of this invention. A semiconductor device of this example regards a semiconductor device which is formed, stacking in layers a plurality of semiconductor packages of Example 12 (FIG. 13).

In the semiconductor device shown in FIG. 14, the first semiconductor package 10A of the lower berth is mounted on the main semiconductor chip 24, and the second semiconductor package 10B of the upper berth is further mounted on it.

In semiconductor package 10B of an upper berth, since the level difference is formed as cut and lacked in the location corresponding to the terminal for external connection of semiconductor package 10A of the lower berth, it is easy to make wire bonding to the terminal for external connection, and the height of the whole stacked layer can be suppressed low.

When making it such a structure, it will become possible to stack in layers many semiconductor packages of the same size of structure which were explained in Example 12 (FIG. 13).

This example is the structure of stacking semiconductor package 10 of the same size in layers, and performing wire bonding in the four directions.

### Example 14

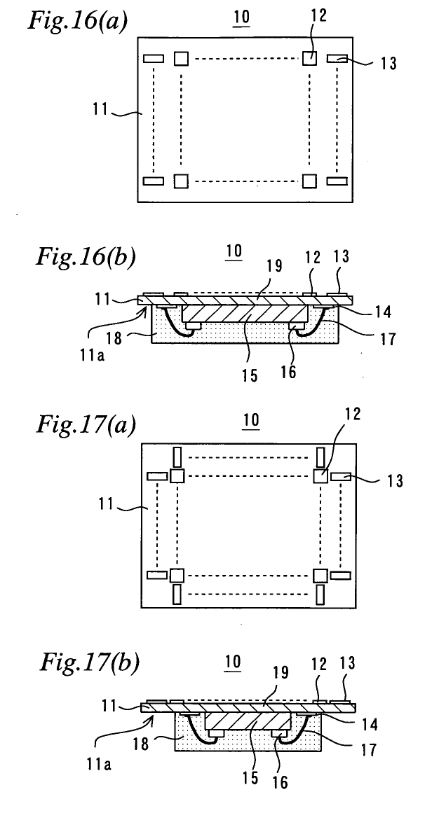

FIG. 15, FIG. 16, and FIG. 17 are the drawings showing the structure of the semiconductor package by another examples of this invention, respectively, (a) is a plan view and (b) is a sectional view.

In the semiconductor package shown in FIG. 15, substrate 11 has peripheral part 11a which extends outside the edge part of molded member 18, and terminals 13 for external connection are arranged at the peripheral part 11a of substrate 11.

In other words, terminals 13 for external connection of substrate 11 are arranged outside terminals 14 for internal connection. Molded member 18 is formed so that terminal 14 for internal connection may be wrapped in the range which does not reach the region corresponding to terminal 13 for external connection.

Namely, in the semiconductor package shown in FIG. 15, a level difference is not formed in molded member 18 (mold), but molded member 18 is formed in the range which avoids the locating position of terminals 13 (pad) for external connection at least of the front surface (main surface) of interposer substrate 11.

When doing in this way, it will become easy to stack many semiconductor packages 10 of the same size in layers.

Semiconductor packages 10 of FIG. 16 and FIG. 17 as well, like FIG. 15, substrate 11 has peripheral part 11a extending outside the edge part of molded member 18, and terminals 13 for external connection are arranged at the peripheral part 11a of substrate 11.

As differences of FIG. 15, FIG. 16, and FIG. 17, in the thing of FIG. 15, one row of terminals 12 for a test are arranged, and one row of terminals 13 for external connection are arranged at facing two sides of the front surface of substrate 11, respectively. In the thing of FIG. 16, one row of terminals 13 for external connection are arranged at facing two sides of the front surface of substrate 11, respectively, and one row of terminals 12 for a test are arranged annularly at four sides of substrate 11. In the thing of FIG. 17, one row of terminals 13 for external connection are arranged annularly at the outermost periphery of the four sides of substrate 11, and one row of terminals 12 for a test are annularly arranged on four sides of substrate 11 in the adjoining inside.

### Example 15

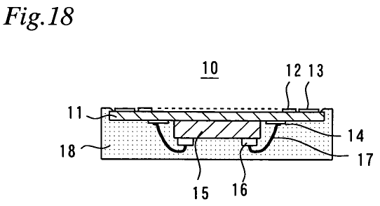

FIG. 18 is a sectional view showing the structure of the semiconductor package by another example of this invention.

In the semiconductor package shown in FIG. 18, while molded member 18 is formed on the back surface of substrate 11 with fixed thickness, it is formed so that the rim end portion of substrate 11 may be wrapped in even to the opposite side (even to above).

That is, in the semiconductor package shown in FIG. 18, molded member 18 (mold) may not be limited to the end portion of interposer substrate 11, but covers to the front surface, wrapping the end portion of interposer substrate 11 so that the end portion of interposer substrate 11 may not be exposed. When making like this, there is an effect that peeling between the interface of interposer substrate 11 and molded member 18 (mold) does not occur easily.

### INDUSTRIAL APPLICABILITY

According to the present invention, a semiconductor device which combined a semiconductor package beforehand encapsulated with another semiconductor chip can be obtained. Hereby, a semiconductor package which was encapsulated and tested beforehand can be operated combining a chip whose function is different, and it becomes easy to obtain a systematized semiconductor device.

1-19. (canceled)

20. A semiconductor package, comprising:
a substrate in which a plurality of terminals for a test and a plurality of terminals for external connection are arranged over a front surface, a plurality of terminals for internal connection are arranged over a back surface, and an internal connection of the terminal for internal connection is made to the desired terminal for a test and/or the terminal for external connection;
at least one semiconductor chip in which a plurality of surface terminals connected to an internal circuit are formed over a front surface, and which is arranged so that a back surface may face the back surface of the substrate;
a wiring which connects the surface terminal of the semiconductor chip to the desired terminal for internal connection of the substrate; and
a molded member which seals the semiconductor chip over the back surface of the substrate.

21. A semiconductor package according to claim 20, wherein
a predetermined action can be made to the semiconductor chip via the terminal for external connection of the substrate by a desired connection between the surface terminal of the semiconductor chip, and the terminal for internal connection of the substrate, and a desired connection between the terminal for internal connection and the terminal for external connection of the substrate.

22. A semiconductor package according to claim 21, wherein
two or more groups of the terminals for internal connection of the substrate are formed; and
a different action can be made to the semiconductor chip by a first desired connection between the terminal for internal connection of a first group, and the terminal for external connection, or a second desired connection between the terminal for internal connection of a second group, and the terminal for external connection, and a desired connection between the surface terminal of the semiconductor chip, and the terminal for internal connection of the first group or the second group of the substrate.

23. A semiconductor package according to claim 20, wherein
a predetermined action of the semiconductor chip can be tested via the terminal for a test of the substrate by a desired connection between the surface terminal of the semiconductor chip, and the terminal for internal connection of the substrate, and a desired connection between the terminal for internal connection and the terminal for a test of the substrate.

24. A semiconductor package according to claim 20, wherein
in the substrate, an arrangement area of the terminals for a test and an arrangement area of the terminals for external connection are separated.

25. A semiconductor package according to claim 24, wherein
in the substrate, the arrangement area of the terminal for external connection is arranged at a periphery of the substrate, and the arrangement area of the terminal for a test is arranged at an inner portion except the periphery of the substrate.

26. A semiconductor package according to claim 24, wherein
in the substrate, the arrangement area of the terminal for external connection is arranged at a periphery of facing two sides of the substrate, the arrangement area of the terminal for a test is arranged at a periphery of another facing two sides of the substrate, and a non-terminal area where a terminal is not arranged is formed in a central part of the substrate.

27. A semiconductor package according to claim 24, wherein
in the substrate, the arrangement area of the terminal for external connection is arranged at a periphery of the substrate, the arrangement area of the terminal for a test is arranged at an inner portion which adjoins the periphery of the substrate, and a non-terminal area where a terminal is not arranged is formed in a central part of the substrate.

28. A semiconductor package according to claim 20, wherein
in the substrate, the terminal for internal connection is arranged at a periphery of the substrate.

29. A semiconductor package according to claim 20, wherein
the one or more semiconductor chips are two or more semiconductor chips stacked in layers.

30. A semiconductor package according to claim 20, wherein
a spacer exposed from the molded member is arranged over the front surface of the semiconductor chip.

31. A semiconductor package according to claim 20, wherein
a part of the wiring is exposed over a front surface of the molded member.

32. A semiconductor package according to claim 20, wherein
an adhesive member is adhered to a front surface of the molded member.

33. A semiconductor package according to claim 24, wherein
the molded member is formed over the back surface of the substrate with fixed thickness, and is formed with relatively small thickness in a portion corresponding to the arrangement area of the terminal for external connection of the substrate.

34. A semiconductor package according to claim 26, wherein
the substrate has a peripheral part extended outside a periphery side part of the molded member, and the terminal for external connection is arranged at the peripheral part of the substrate.

35. A semiconductor package according to claim 27, wherein
the substrate has a peripheral part extended outside a periphery side part of the molded member, and the terminal for external connection is arranged at the peripheral part of the substrate.

36. A semiconductor package according to claim 24, wherein
the molded member is formed over the back surface of the substrate with fixed thickness, and is formed so that a rim end portion of the substrate may be wrapped in.

37. A semiconductor package according to claim 20, wherein
the terminal for a test, the terminal for external connection and the terminal for internal connection of the substrate, and the surface terminal of the semiconductor chip are pads for wire bonding, and the wiring is a wire for bonding.

38. A semiconductor device, comprising:
a main substrate in which a plurality of main terminals for connection are arranged over a main front surface, a plurality of main terminals for external connection are arranged over a back surface, and an internal connection of the main terminal for connection is made to the desired main terminal for external connection;
at least one main semiconductor chip in which a plurality of surface terminals connected to an internal circuit are formed in a main front surface, and which is arranged so that a back surface may face the front surface of the main substrate;
at least one semiconductor package according to claim 1 arranged so that the molded member may face the front surface of the main semiconductor chip;
wirings which connect the surface terminal of the main semiconductor chip, and the terminal for external connection of the semiconductor package to the desired main terminal for connection of the main substrate; and
a main molded member which seals the main semiconductor chip and the semiconductor package over the front surface of the main substrate.

39. A semiconductor device according to claim 38, wherein
the at least one semiconductor package is two or more semiconductor packages stacked in layers into a lower berth and an upper berth, and the semiconductor package of the upper berth is laid in a non-terminal area where the terminal for external connection is not arranged of the semiconductor package of the lower berth.
